(19) United States
(12) Patent Application Publication
(10) Pub. No.: US 2013/0130513 A1
(43) Pub. Date: May 23, 2013

(54) INTERLAYER INSULATING LAYER FORMING METHOD AND SEMICONDUCTOR DEVICE

(71) Applicants: Kotaro Miyatani, Nirasaki-City (JP); Takenao Nemoto, Nirasaki-City (JP); Takuya Kurotori, Nirasaki-City (JP); Yasuo Kobayashi, Sendai-City (JP); Toshihisa Nozawa, Sendai-City (JP)

(72) Inventors: Kotaro Miyatani, Nirasaki-City (JP); Takenao Nemoto, Nirasaki-City (JP); Takuya Kurotori, Nirasaki-City (JP); Yasuo Kobayashi, Sendai-City (JP); Toshihisa Nozawa, Sendai-City (JP)

(73) Assignee: TOKYO ELECTRON LIMITED, Tokyo (JP)

(21) Appl. No.: 13/811,012

(22) PCT Filed: Jul. 20, 2011
(86) PCT No.: PCT/JP2011/066395

§ 371 Date: Feb. 7, 2013

(30) Foreign Application Priority Data
Jul. 21, 2010 (JP) 2010-164212

(51) Int. Cl. H01L 21/02

(52) U.S. Cl. CPC H01L 21/02274
USPC 438/782

(57) ABSTRACT

The interlayer insulating layer forming method for forming an interlayer insulating layer of a semiconductor device via a plasma CVD method includes: carrying a substrate into a depressurized processing container; supplying a plasma generating gas to a first space spaced apart from the substrate; exciting the plasma generating gas in the first space; and supplying a raw material gas including a boron compound that includes at least a hydrogen group or hydrocarbon group, to a second space between the first space and the substrate. Also, a semiconductor device is interconnected in a multilayer through an interlayer insulating layer having an amorphous structure including boron, carbon, and nitrogen, wherein, in the interlayer insulating layer, a hydrocarbon group or an alkyl amino group is mixed in the amorphous structure comprising hexagonal boron nitride and cubic boron nitride.

### TECHNICAL FIELD

The present invention relates to an interlayer insulating layer forming method wherein an interlayer insulating layer of a semiconductor device interconnected in a multilayer on a substrate is formed via a plasma chemical vapor deposition (CVD) method, and a semiconductor device interconnected in a multilayer with an interlayer insulating layer inbetween.

### BACKGROUND ART

SiOF, SiCO, or organic-based films using conventional SiO₂ as a basic material have been developed as interlayer insulating layers of an ultra-large scale integration (ULSI) having a multilayer interconnection structure. However, due to further integration of the ULSI in response to the miniaturization and high performance of recent electronic devices, a wire delay caused by an increase of a wire length has exceeded a gate delay that is a characteristic of a transistor. In order to solve the wire delay problem, an RC time constant of a wire needs to be reduced, and specifically, a dielectric constant of an interlayer insulating layer has been decreased to reduce a capacitive component of the wire.

For example, a method of preparing an interlayer insulating layer in a porous structure has been suggested as a method of decreasing a dielectric constant of an interlayer insulating layer. Also, an interlayer insulating layer, including at least one of boron, carbon, and nitrogen as a main element and two or more regions where bonding structures of atoms are different, is disclosed (for example, Patent References 1 and 2).

### PRIOR ART REFERENCE

### Patent Reference

(Patent Reference 1) Japanese Laid-Open Patent Publication No. 2001-313335
(Patent Reference 2) Japanese Laid-Open Patent Publication No. 2009-81179

### DISCLOSURE OF THE INVENTION

### Technical Problem

However, in an interlayer insulating layer having a porous structure, a mechanical strength and anti-moisture absorption may be low, a chemical liquid may diffuse into a vacancy of the interlayer insulating layer from a side wall of a wire groove, and a barrier metal coverage may be poor. An interlayer insulating layer according to the Patent References 1 and 2 has a higher dielectric constant than the interlayer insulating layer having the porous structure, and thus cannot sufficiently overcome a wire delay problem.

Considering such circumstances, the present invention provides an interlayer insulating layer capable of forming an interlayer insulating layer with a low dielectric constant and excellent mechanical strength and anti-moisture absorption, compared to an interlayer insulating layer having a porous structure according to a conventional technology.

Also, the present invention provides a semiconductor device capable of reducing a wire delay by forming an interlayer insulating layer with a low dielectric constant and excellent mechanical strength and anti-moisture absorption, compared to an interlayer insulating layer according to a conventional technology.

### Technical Solution

According to an aspect of the present invention, there is provided an interlayer insulating layer forming method for forming an interlayer insulating layer of a semiconductor device via a plasma CVD method, the interlayer insulating layer including: carrying a substrate into a depressurized processing container; supplying a plasma generating gas to a first space spaced apart from the substrate; exciting the plasma generating gas in the first space; and supplying a raw material gas including a boron compound that includes at least a hydrogen group or hydrocarbon group, to a second space between the first space and the substrate.

In the present invention, since the raw material gas is supplied to the second space spaced apart from the first space towards the substrate, instead of the first space where plasma is generated, some molecules which are included in the raw material gas of the interlayer insulating layer are not completely dissociated and are deposited on the substrate the way they are. Accordingly, the interlayer insulating layer having a space in a molecule level is formed. Since the interlayer insulating layer having a space therein has a low dielectric constant compared to an interlayer insulating layer that does not have a space, it may be possible to reduce a wire delay. Also, since the space is in the molecule level, a mechanical strength and anti-moisture absorption of the interlayer insulating layer may not be decreased, a chemical liquid may not be diffused from a side wall of a wire groove to a vacancy, and a barrier metal coverage may not be poor.

Also, obviously, the supplying of the plasma generating gas, the exciting of the in plasma generating gas, and the supplying of the raw material gas may be simultaneously performed

According to another aspect of the present invention, there is provided a semiconductor device interconnected in a multilayer with an interlayer insulating layer inbetween having an amorphous structure including boron, carbon, and nitrogen, wherein, in the interlayer insulating layer, a hydrocarbon group or an alkyl amino group is mixed in the amorphous structure including hexagonal boron nitride and cubic boron nitride.

In the interlayer insulating layer of the present invention, the hydrocarbon group or the alkyl amino group is mixed in the amorphous structure including the hexagonal boron nitride and the cubic boron nitride. In other words, the interlayer insulating layer has a space in a molecule level. Since the interlayer insulating layer having a space therein has a low dielectric constant compared to an interlayer insulating layer that does not have a space, it may be possible to reduce a wire delay. Also, since the space is in the molecule level, a mechanical strength and anti-moisture absorption of the interlayer insulating layer may not be decreased, a chemical liquid may not be diffused from a side wall of a wire groove to a vacancy, and a barrier metal coverage may not be poor.

Also, since the cubic boron nitride generally has a higher elastic modulus than the hexagonal boron nitride, the cubic boron nitride has an excellent mechanical strength. Accordingly, the interlayer insulating layer according to the present invention has an excellent mechanical strength since it includes the cubic boron nitride.

### Advantageous Effects

According to an interlayer insulating layer forming method of the present invention, an interlayer insulating layer with a low dielectric constant and excellent mechanical strength and anti-moisture absorption, compared to an interlayer insulating layer having a porous structure according to a conventional technology, may be formed.

Also, according to a semiconductor device of the present invention, a wire delay may be reduced by forming an interlayer insulating layer with a low dielectric constant and excellent mechanical strength and anti-moisture absorption, compared to an interlayer insulating layer according to a conventional technology.

### BRIEF DESCRIPTION OF THE DRAWINGS

FIG. 1 is a schematic diagram showing a structure of an interlayer insulating layer forming apparatus according to an embodiment of the present invention;

FIG. 2 is a plan view schematically showing a structure of a slot plate;

FIG. 3 is a plan view schematically showing a structure of a second gas introduction unit;

FIG. 4 is a flowchart showing a process order of a process controller according to an interlayer insulating layer forming method;

FIG. 5 is a graph showing a relationship between the distribution of plasma generated by an interlayer insulating layer forming apparatus and an electron temperature;

FIG. 6 is a lateral cross-sectional view showing a structure of a semiconductor device according to the embodiment;

FIG. 7 is a cross-sectional view schematically showing an interlayer insulating layer;

FIG. 8 is a graph showing results of chemical structure analysis of an interlayer insulating layer according to Fourier transform infrared spectroscopy;

FIG. 9 is a table showing characteristics of hexagonal boron nitride and cubic boron nitride;

FIG. 10A is a graph showing a relationship between a bonding structure included in an interlayer insulating layer and a film characteristic;

FIG. 10B is a graph showing a relationship between a bonding structure included in an interlayer insulating layer and a film characteristic;

FIG. 11 is a graph showing a moisture amount separated during an annealing process of an interlayer insulating layer according to time;

FIG. 12 is a flowchart showing a process order according to an interlayer insulating layer forming method according to Modified Example 1; and

FIG. 13 is a flowchart showing a process order according to an interlayer insulating layer forming method according to Modified Example 2.

### BEST MODE FOR CARRYING OUT THE INVENTION

Hereinafter, one or more embodiments of the present invention will be described with reference to the accompanying drawings.

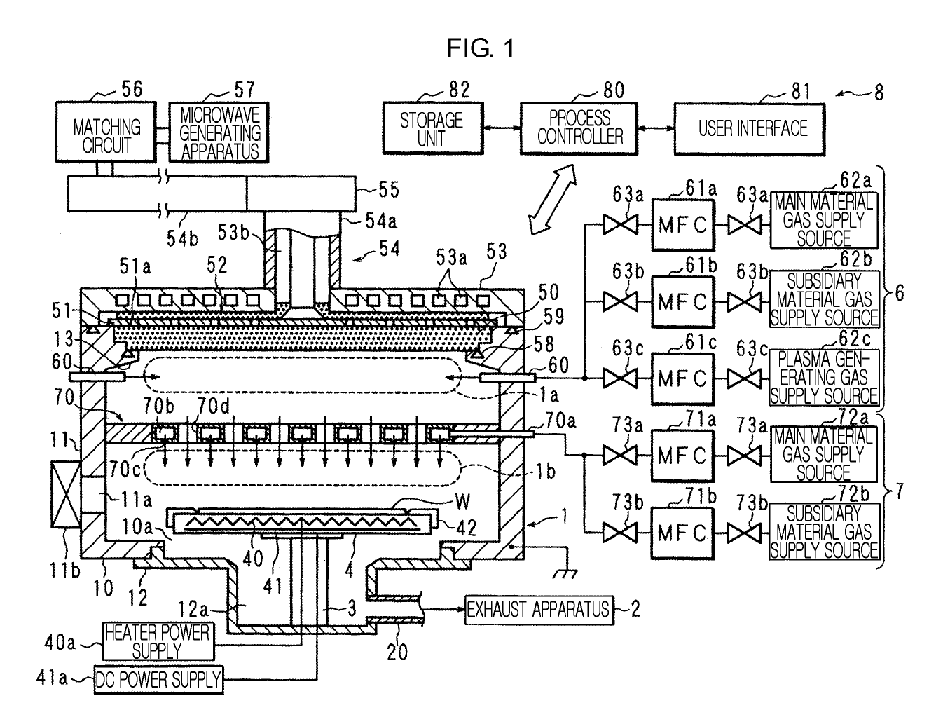

FIG. 1 is a schematic diagram showing a structure of an interlayer insulating layer forming apparatus according to an embodiment of the present invention. The interlayer insulating layer forming apparatus according to the present embodiment is, for example, a radial line slot antenna type microwave plasma CVD apparatus that is used to perform an interlayer insulating layer forming method according to an embodiment. The interlayer insulating layer forming apparatus includes a processing chamber 1 that is configured to be airtight and approximately has a grounded cylindrical shape. The processing chamber 1 is formed of, for example, an aluminum material, and has a bottom wall 10 that has a flat circular ring shape with a circular opening portion 10a approximately at a center portion, a side wall 11 that is provided around the bottom wall 10, and an opened top. Also, a liner having a cylindrical shape and formed of quartz may be formed on an inner circumference of the processing chamber 1.

An exhaust chamber 12 having a cylindrical shape with a downward protruding bottom is formed on the bottom wall 10 of the processing chamber 1 so as to communicate with the opening portion 10a. An exhaust pipe 20 is provided at a side wall of the exhaust chamber 12, and an exhaust apparatus 2 including a high speed vacuum pump is connected to the exhaust pipe 20. By activating the exhaust apparatus 2, a gas inside the processing chamber 1 is uniformly discharged into a space 12a of the exhaust chamber 12, and exhausted through the exhaust pipe 20. Accordingly, it is possible to depressurize an inside of the processing chamber 1 to a predetermined vacuum level at a high speed.

Also, a transfer inlet/outlet 11a and a gate valve 11b closing and opening the transfer inlet/outlet 11a are provided at the side wall 11 of the processing chamber 1 so as to transfer a semiconductor wafer W (hereinafter, referred to as a wafer W) between with a transfer chamber (not shown) adjacent to the interlayer insulating layer forming apparatus.

A pillar-shaped member 3 formed of ceramic, such as AlN, protrudes approximately perpendicular to a bottom center of the exhaust chamber 12, and a susceptor 4 supporting the wafer W that is a target substrate on which a plasma CVD process is to be performed is provided at a leading end portion of the pillar-shaped in member 3. The susceptor 4 has a disk shape, and a guide ring 42 for guiding the wafer W is provided at an outer edge portion of the susceptor 4. A heater 40 for heating the wafer W and an electrode 41 for electrostatically holding the wafer W are embedded in the susceptor 4, wherein a heater power supply 40a and a DC power supply 41a are respectively connected to the heater 40 and the electrode 41. Also, a wafer support pin (not shown) for supporting and elevating the wafer W is provided to protrude and retract with respect to a surface of the susceptor 4. Also, a high frequency power supply (not shown) for applying a bias to the wafer W that is a target substrate may be provided at the susceptor 4.

A support 13 having a ring shape is provided along a peripheral portion of an opening portion formed at a top of the processing chamber 1. A dielectric window 50 formed of a dielectric material, for example, ceramic such as quartz or Al₂O₃, through which microwaves penetrate, and having a disk shape is hermetically formed at the support 13 through a seal member 58.

A slot plate 51 having a disk shape is provided at a top of the dielectric window 50 to face the susceptor 4.

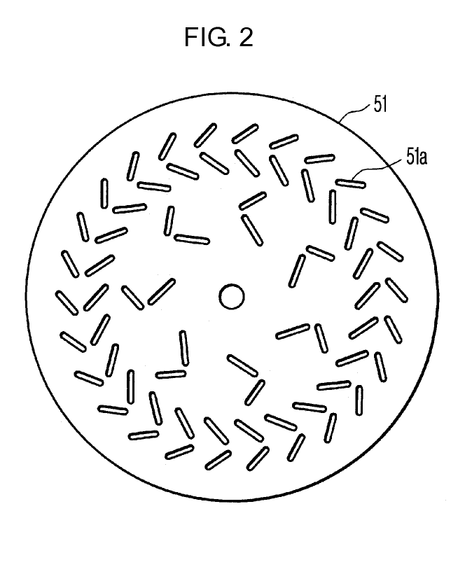

FIG. 2 is a plan view schematically showing a structure of the slot plate 51.

The slot plate 51 is configured to surface-contact the dielectric window 50. The slot plate 51 is formed of a conductor, for example, a copper plate or aluminum plate whose surface is coated with gold. The slot plate 51 includes a plurality of microwave radiation slots 51a that penetrate through the slot plate 51 in a predetermined pattern. The slot plate 51 constitutes a radial line slot antenna type antenna. In other words, the microwave radiation slot 51a, for example, has a long groove shape, and a pair of adjacent microwave radiation slots 51a are adjacently disposed to approximately form an L shape. The plurality of microwave radiation slots 51a that are paired up are arranged in a concentric circular shape. In detail, seven pairs of the microwave radiation slots 51a are formed at an inner circumference of the slot plate 51 and twenty six pairs of the microwave radiation slots 51a are formed at an outer circumference of the slot plate 51. Lengths and intervals of the microwave radiation slots 51a are determined according to the wavelength of microwaves or the like.

A dielectric plate 52 having a higher dielectric constant than vacuum is configured to surface-contact a top surface of the slot plate 51. The dielectric plate 52 in includes a dielectric circular plate portion having a flat shape. An aperture portion is formed approximately at a center portion of the dielectric circular plate portion. Also, a microwave incident portion having a cylindrical shape protrudes from a periphery of the aperture portion approximately perpendicular to the dielectric circular plate portion.

A shield cover body 53 having a disk shape is provided on a top surface of the processing chamber 1 to cover the slot plate 51 and the dielectric plate 52. The shield cover body 53 is formed of a metal material, such as aluminum or stainless steel. A space between the top surface of the processing chamber 1 and the shield cover body 53 is sealed by a seal member 59.

A cover body cooling water flow path 53a is formed inside the shield cover body 53, and thus the slot plate 51, the dielectric window 50, the dielectric plate 52, and the shield cover body 53 are cooled down by flowing cooling water through the cover body cooling water flow path 53a. Also, the shield cover body 53 is grounded.

An opening portion 53b is formed at a center of a top wall of the shield cover body 53, and a waveguide 54 is connected to the opening portion 53b. The waveguide 54 includes a coaxial waveguide 54a having a circular cross sectional shape that protrudes upward from the opening portion 53b of the shield cover body 53, and a rectangular waveguide 54b that is connected to a top portion of the coaxial waveguide 54a and has a rectangular cross sectional shape extending in a horizontal direction, wherein a microwave generating apparatus 57 is connected to an end of the rectangular waveguide 54b through a matching circuit 56. Microwaves, for example, microwaves at a 2.45 GHz frequency, generated by the microwave generating apparatus 57 propagate to the slot plate 51 through the waveguide 54. Alternatively, 3.35 GHz, 2.45 GHz, 1.98 GHz, and 915 MHz may be used as a frequency of the microwaves. A mode converter 55 is provided at an end of a connecting portion with the coaxial waveguide 54a of the rectangular waveguide 54b. The coaxial waveguide 54a includes a coaxial outer conductor having a container shape and a coaxial inner conductor disposed along a center line of the coaxial outer conductor, wherein a bottom portion of the coaxial inner conductor is connected and fixed to a center of the slot plate 51. Also, the microwave incident portion of the dielectric plate 52 is inserted into the coaxial waveguide 54a.

Also, first and second gas introduction units 60 and 70 are respectively formed at in top and bottom of the side wall 11 of the processing chamber 1. The first gas introduction unit 60 is for example, a member having a nozzle shape disposed around the side wall 11, wherein a first gas supply system 6 for supplying a raw material gas of an interlayer insulating layer and a plasma generating gas for plasma generation is connected to the first gas introduction unit 60 to supply the raw material gas and the plasma generating gas to a first space 1a at an upper portion of the processing chamber 1. The first space 1a is referred to as a plasma generating region.

The first gas supply system 6 includes a main material gas supply source 62a containing a main material gas of the interlayer insulating layer, a subsidiary material gas supply source 62b containing a subsidiary material gas of the interlayer insulating layer, and a plasma generating gas supply source 62c containing a plasma generating gas. The main material gas supply source 62a, the subsidiary material gas supply source 62b, and the plasma generating gas supply source 62c are each connected to the first gas introduction unit 60 through a respective pipe. Also, mass flow controllers 61a, 61b, and 61c and opening/closing valves 63a, 63b, and 63c on both sides thereof are provided along the respective pipe connected each gas supply source, and thus a gas being supplied may be switched or a flow rate may be controlled. The flow rate is controlled by a process controller 80 described below.

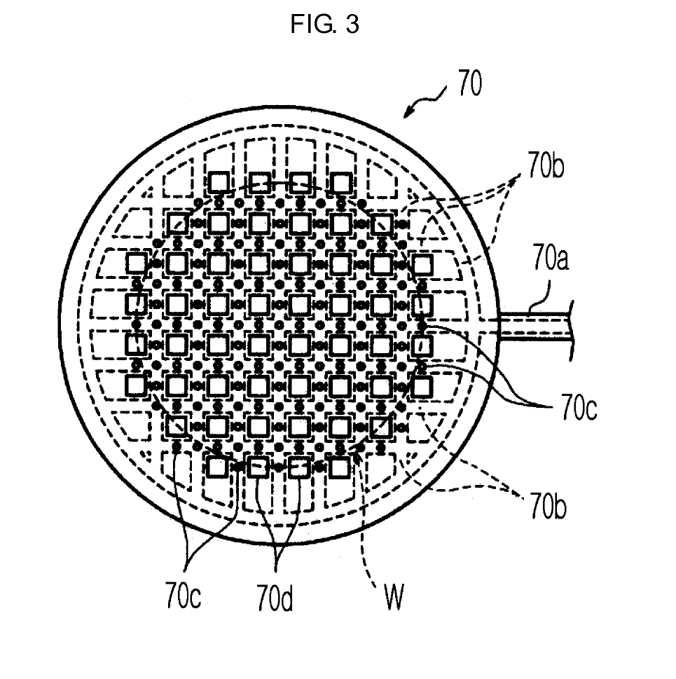

FIG. 3 is a plan view schematically showing a structure of the second gas introduction unit 70. The second gas introduction unit 70 includes gas flow paths 70b having a lattice shape and a plurality of gas discharge holes 70c formed in the gas flow paths 70b having the lattice shape. Space portions 70d are formed between the gas flow paths 70b having the lattice shape, and the gas discharge holes 70c are formed in the gas flow paths 70b towards the susceptor 4. A second gas pipe 70a extending outside the processing chamber 1 is connected to the gas flow path 70b. The second gas pipe 70a is connected to a second gas supply system 7 for supplying the raw material gas of the interlayer insulating layer so as to supply the raw material gas to a second space 1b located lower than the first space 1a, i.e., a region spaced apart towards a substrate from the first space 1a that is the plasma generating region. The second space 1b is referred to as a diffused plasma region.

The second gas supply system 7 includes a main material gas supply source 72a containing a main material gas of the interlayer insulating layer and a subsidiary in material gas supply source 72b containing a subsidiary material gas of the interlayer insulating layer. The main material gas supply source 72a and the subsidiary material gas supply source 72b are each connected to the second gas introduction unit 70 through a respective pipe. Also, mass flow controllers 71a and 71b and opening/closing valves 73a and 73b on both sides thereof are provided along the respective pipe connected to each gas supply source, and thus a supplied gas may be switched or a flow rate may be controlled. The flow rate may be controlled by the process controller 80 described below, like the first gas supply system 6.

Table 1 below shows examples of types of gases that are supplied to the processing chamber 1 and target place of supply gases.

TABLE 1

| | | Target Place of |
|---|---|---|
| Type of Supply Gas | | Supply Gas |
| Main Material Gas | Alkyl Boron | Second Space |
| | Alkyl Amino Boron | Second Space |
| Subsidiary Material Gas | Nitrogen or Ammonia | First Space |
| | Hydrocarbon | First Space |
| Plasma Generating Gas | Argon, Helium, Xenon, | First Space |
| | Krypton | |

The main material gas is a gas including at least boron. For example, the main material gas is diborane, alkyl boron, or alkyl amino boron. Alkyl boron is a boron compound having a hydrogen group or a hydrocarbon group, and for example, trimethylboran (B—(CH₃)₃) or triethylboron (B—(C₂H₅)₃) is used. When a liquid raw material is used at room temperature as the main material gas, the liquid raw material may be gasified by using a vaporizer (not shown). Here, an inert gas may be used as a carrier gas.

Alkyl amino boron is a boron compound having a hydrogen or hydrocarbon group and amine, and for example, trisdimethyl amino boron (TMAB) may be used. A structural formula of TMAB is represented by the chemical formula below.

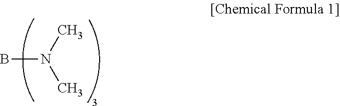

Alternatively, alkyl amino boron represented by chemical formulas below may be used as the main material gas.

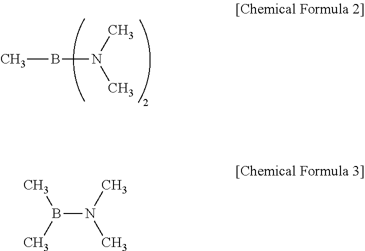

The subsidiary material gas is, for example, nitrogen, ammonia, or hydrocarbon.

The plasma generating gas is, for example, an inert gas. In detail, the inert gas is argon, helium, xenon, krypton, or the like. In the above embodiment, the main material gas and the subsidiary material gas are supplied to the processing chamber 1, but only the main material gas may be supplied to the processing chamber 1 according to a target composition of the interlayer insulating layer. Also, obviously, the main material gas, the subsidiary material gas, and the plasma generating gas described above are only examples, and another raw material gas may be used as long as boron, carbon, and nitrogen are contained in molecules and an interlayer insulating layer containing boron, carbon, and nitrogen is formed via plasma CVD.

Also, the interlayer insulating layer forming apparatus includes a control unit 8 for controlling each component of the interlayer insulating layer forming apparatus. The control unit 8 includes, for example, the process controller 80, a user interface 81, and a storage unit 82. The user interface 81, including a keyboard that performs an input manipulation of a command for a process manager to manage the interlayer insulating layer forming apparatus, and a display that visualizes and displays an activating state of in the interlayer insulating layer forming apparatus, is connected to the process controller 80. Also, the storage unit 82 storing a control program for realizing various processes executed on the interlayer insulating layer forming apparatus by controlling the process controller 80, and a process control program recorded with process condition data or the like is connected to the process controller 80. The process controller 80 calls a predetermined process control program according to an indication from the user interface 81 from the storage unit 82 to execute the program, and thus a desired process in the interlayer insulating layer forming apparatus is performed under a control of the process controller 80.

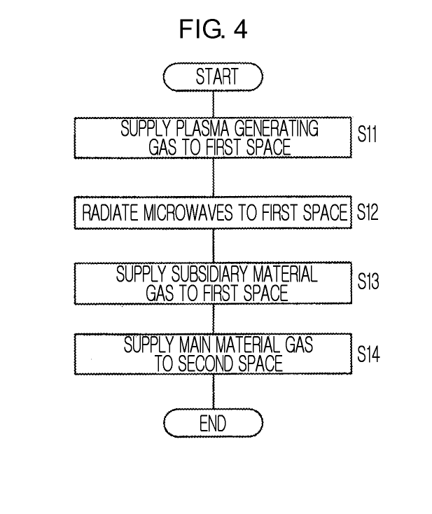

FIG. 4 is a flowchart showing a process order of the process controller 80 according to an interlayer insulating layer forming method. Hereinafter, a process order after the wafer W, including a conduction layer where various semiconductor elements are disposed, is transferred to the processing chamber 1 will be described. The process controller 80 supplies the plasma generating gas to the first space 1a in operation S11 by opening the opening/closing valve 63c of the plasma generating gas supply source 62c. Then, the process controller 80 drives the microwave generating apparatus 57 to radiate microwaves to the first space 1a in operation S12. By supplying the plasma generating gas and radiating the microwaves to the first space la, plasma may be generated in the first space 1a.

Then, the process controller 80 supplies the subsidiary material gas of the interlayer insulating layer to the first space la in operation 513 by opening the opening/closing valve 63b of the subsidiary material gas supply source 62b in the first gas supply system 6. Then, the process controller 80 supplies the main material gas of the interlayer insulating layer to the second space 1b in operation 514 by opening the opening/closing valve 73a of the main material gas supply source 72a in the second gas supply system 7.

Process conditions are as follows: A temperature of the wafer W is from 0 to 400° C., and temperatures of the side wall 11 and the dielectric window 50 of the processing chamber 1 are from 0 to 200° C. According to plasma conditions, pressure is from 1 to 50 Pa, a frequency of microwaves is 2.45 GHz, and microwave power is from 1500 to 5000 W. Here, the plasma conditions are conditions of an apparatus for a 300 mm wafer. According to a range of gas flow rates, the main material gas is from in 50 to 300 sccm, a hydrocarbon gas as the subsidiary material gas is from 0 to 500 sccm, and the plasma generating gas is from 0 to 1000 sccm. Also, a flow rate of a hydrocarbon gas as the subsidiary material gas is equal to a flow rate of CH₄ conversion.

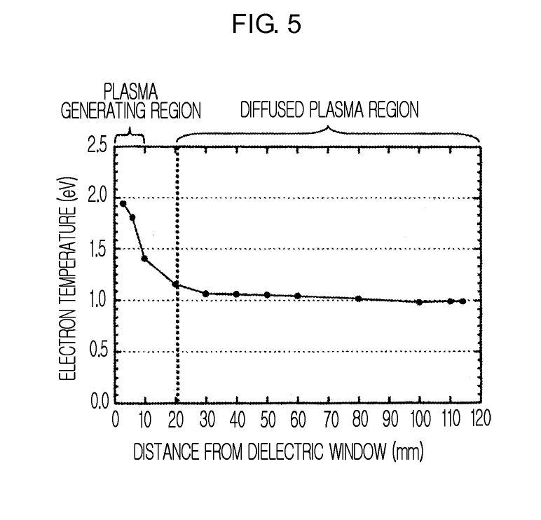

FIG. 5 is a graph showing a relationship between the distribution of plasma generated by an interlayer insulating layer forming apparatus and an electron temperature, A horizontal axis denotes a distance from a bottom surface of the dielectric window 50 in a vertical direction and a vertical axis denotes an electron temperature of plasma. Also, the distance from the bottom surface of the dielectric window 50 is vertically downward, i.e., a distance towards the susceptor 4 is positive. Also in FIG. 5, a broken line at a location 20 mm away from the dielectric window 50 denotes a location of the second gas introduction unit 70. Also, a distance between the bottom surface of the dielectric window 50 and the top surface of the susceptor 4 is 120 mm.

As shown in FIG. 5, 0 to 10 mm immediately below the dielectric window 50 is a region where the electron density of the plasma is relatively high, and the plasma is generated in that region. The region corresponds to the plasma generating region, i.e., the first space 1a. The plasma generated in the first space 1a diffuses to a lower region of the processing chamber 1. The lower region corresponds to the diffused plasma region, i.e., the second space 1b. Since the electron temperature of the plasma in the second space 1b decreases down to about 1 eV, the raw material gas supplied to the second space 1b is not excessively dissociated but is deposited on the wafer W while maintaining a bond.

Next, a structure of a semiconductor device according to the present embodiment will be described. The semiconductor device according to the present embodiment is an ultra-large scale integration (ULSI) having a multilayer interconnection structure on the wafer W. Hereinafter, an example where an N-channel MOSFET is formed on the wafer W and the N-channel MOSFET is interconnected in a multilayer with an interlayer insulating layer inbetween is described.

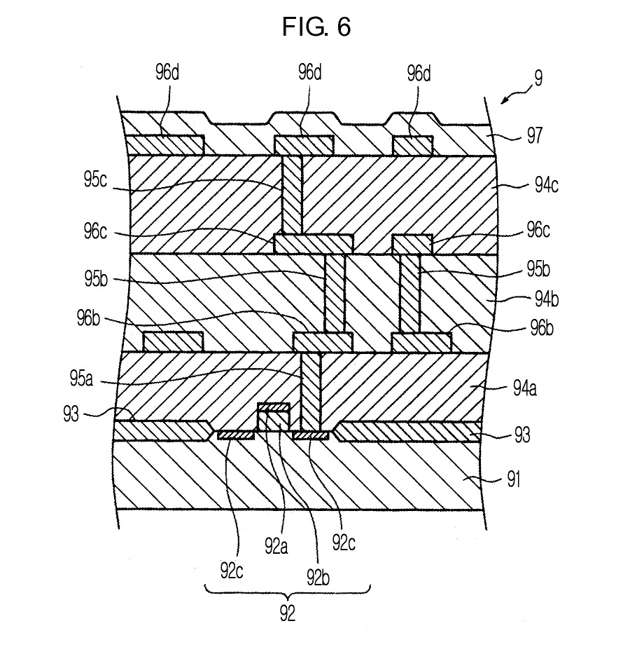

FIG. 6 is a lateral cross-sectional view showing a structure of a semiconductor device 9 according to the embodiment. The semiconductor device 9 includes a p-type wafer substrate 91, an MOSFET 92 formed on the wafer substrate 91, oxide layers 93 in for device separation, interlayer insulating layers 94a through 94c for multilayer interconnection, wire metals 95a through 95c and 96b through 96d, and a passivation film 97.

The MOSFET 92 is formed on and spaced apart from the wafer substrate 91. The MOSFET 92 includes drain/sources 92c and a gate 92a formed by disposing a SiO₂ film 92b between the drain/source 92c.

The interlayer insulating layers 94a through 94c are layers that insulate a plurality of semiconductor elements (not shown) formed by being stacked on a plurality of layers from each other. The interlayer insulating layers 94a through 94c are formed, for example, by using the interlayer insulating layer forming method according to the present embodiment.

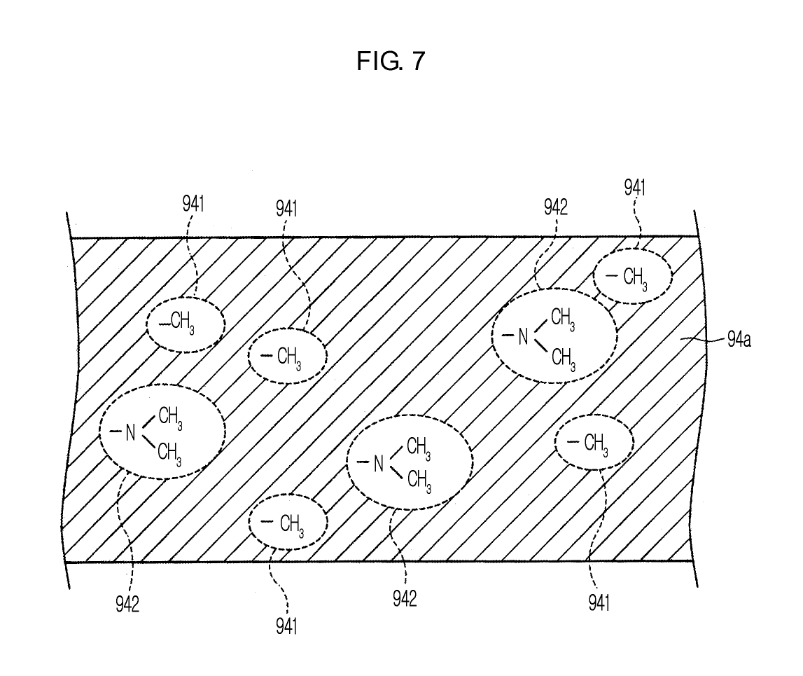

FIG. 7 is a cross-sectional view schematically showing interlayer insulating layers 94a through 94c. The interlayer insulating layers 94a through 94c have an amorphous structure including hexagonal boron nitride and cubic boron nitride, wherein a hydrocarbon group 941 and an alkyl amino group 942 are mixed in the amorphous structure. The amorphous structure of the interlayer insulating layers 94a through 94c is formed as, for example, a plasma CVD apparatus supplies a raw material gas of an interlayer insulating layer to a region where plasma is generated, and boron, carbon, and nitrogen, in which molecules forming the raw material gas are dissociated, are deposited on the wafer substrate 91. Also, by supplying the raw material gas to a low electron temperature region that is spaced apart towards the substrate than the plasma generating region, the hydrocarbon group 941 and the alkyl amino group 942 may be mixed in the amorphous structure. The hydrocarbon group 941 and the alkyl amino group 942 are atom groups generated by partially dissociated molecules which compose raw material gas.

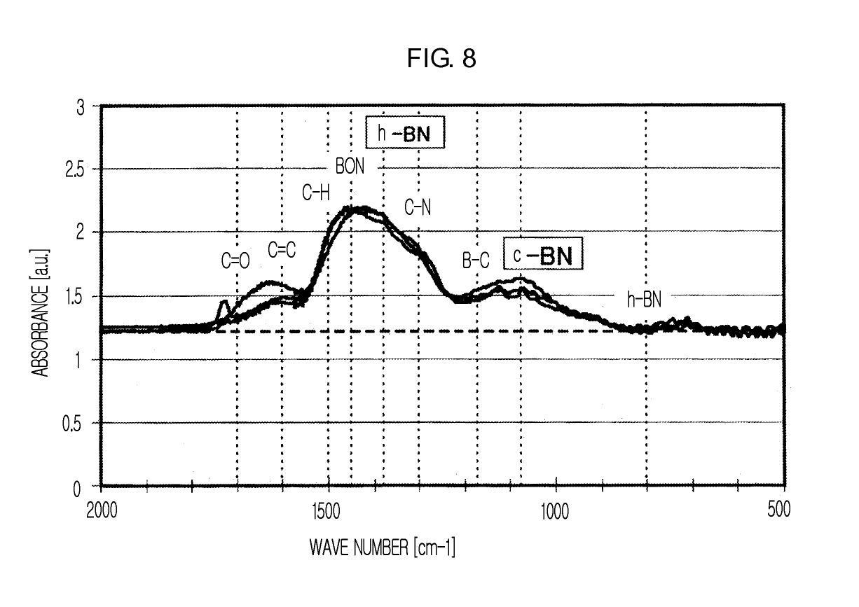

FIG. 8 is a graph showing results of chemical structure analysis of the interlayer insulating layers 94a through 94c according to Fourier transform infrared spectroscopy. A horizontal axis denotes a wave number and a vertical axis denotes absorbance. As shown in the graph of FIG. 8, an infrared light absorption peak of a wave number of about 1400 cm⁻¹ by the hexagonal boron nitride and an infrared light absorption peak of a wave number of about 1070 cm⁻¹ by cubic boron nitride are recognized. Accordingly, it may be determined that the interlayer insulating layers 94a through 94c have the in amorphous structure including the hexagonal boron nitride and the cubic boron nitride.

Also, since infrared light absorption by a C═C bond, C—H bond, B—C bond, C—N bond, or the like is recognized, it may be determined that the hydrocarbon group 941 and the alkyl amino group 942 are mixed in the amorphous structure without being dissociated.

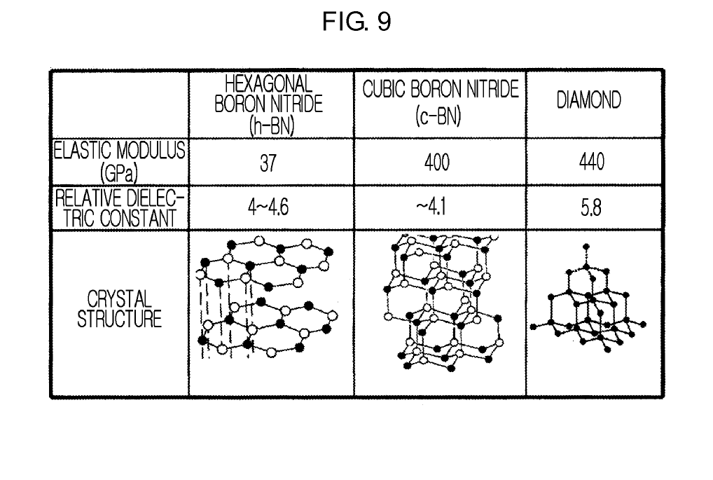

FIG. 9 is a table showing characteristics of hexagonal boron nitride and cubic boron nitride. FIG. 9 schematically shows an elastic modulus, a relative dielectric constant, and a crystal structure of each of hexagonal boron nitride, cubic boron nitride, and diamond. As shown in FIG. 9, the elastic modulus of the cubic boron nitride is 400 GPa, which is an elastic modulus at a level of the diamond. Also, the elastic modulus of the hexagonal boron nitride is 37 GPa, and the hexagonal boron nitride has sufficient mechanical strength. Accordingly, even when the hydrocarbon group 941 and the alkyl amino group 942 are introduced, the interlayer insulating layers 94a through 94c may maintain sufficient mechanical strength. The relative dielectric constants of the hexagonal boron nitride and the cubic boron nitride are both equal to that of SiO₂.

Accordingly, by controlling the introduced amounts of the hydrocarbon group 941 and the alkyl amino group 942, the interlayer insulating layers 94a through 94c that maintain the sufficient mechanical strength while having desired low dielectric constants may be obtained. Specifically, since the interlayer insulating layers 94a through 94c according to the present embodiment have the cubic boron nitride, massive amounts of the hydrocarbon group 941 and the alkyl amino group 942 are introduced, compared to an interlayer insulating layer that does not include cubic boron nitride, thereby promoting a low dielectric constant. Also, when the introduced amounts of the hydrocarbon group 941 and the alkyl amino group 942 are about the same, the interlayer insulating layers 94a through 94c according to the present embodiment include the cubic boron nitride and thus have higher mechanical strength than an interlayer insulating layer that does not include cubic boron nitride.

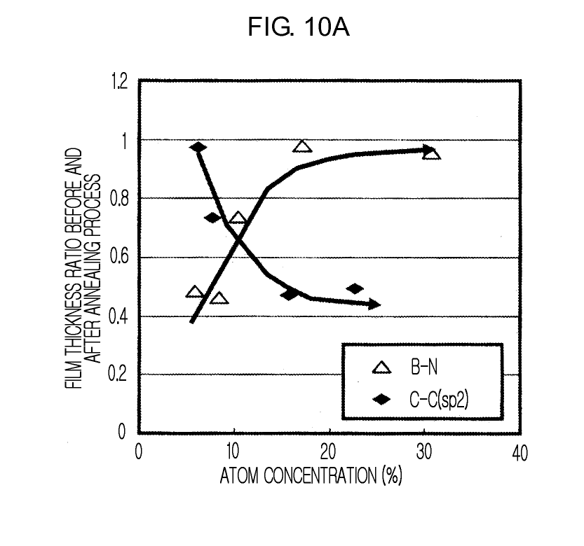

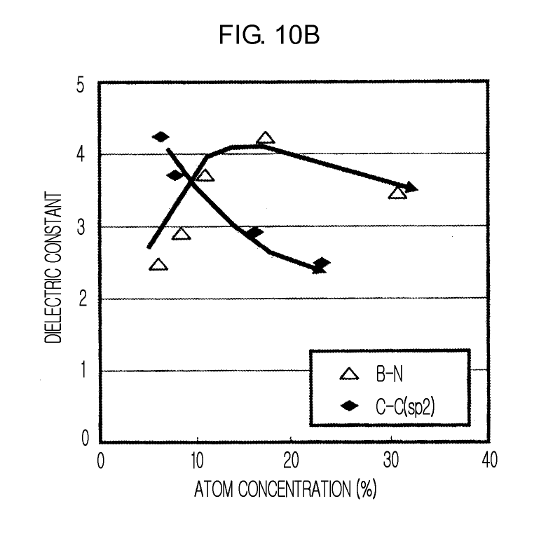

FIGS. 10A and 10B are graphs showing a relationship between a bonding structure included in the interlayer insulating layers 94a through 94c and a film characteristic, FIG. 10A shows a relationship between the atom concentration of a B—N bond and a C—C bond included in the interlayer insulating layers 94a through 94c, and a film thickness ratio of the interlayer insulating layers 94a through 94c before and after in an annealing process. As the film thickness ratio of the interlayer insulating layers 94a through 94c before and after the annealing process is closer to 1, the interlayer insulating layers 94a through 94c may be satisfactory films without shrinkage and have high heat resistance. FIG. 10B shows a relationship between the atom concentration of the B—N bond and the C—C bond included in the interlayer insulating layers 94a through 94c, and dielectric constants of the interlayer insulating layers 94a through 94c. As shown in the graphs of FIGS. 10A and 10B, the heat resistance improves as the atom concentration of the B—N bond in the Interlayer insulating layers 94a through 94c increases higher, but the dielectric constants also tend to increase. Also, as the atom concentration of the C—C bond in the interlayer insulating layers 94a through 94c is increased, the dielectric constants are decreased, but the heat resistance is low. Accordingly, the atom concentration of the C—C bond introduced to the interlayer insulating layers 94a through 94c, i.e., the introduced amounts of the hydrocarbon group 941 and the alkyl amino group 942, is suitably determined to a ratio of the dielectric constants and heat resistance required in the interlayer insulating layers 94a through 94c. According to the interlayer insulating layer forming apparatus of the present embodiment, the introduced amounts of the hydrocarbon group 941 and the alkyl amino group 942 are controlled by adjusting the amounts of the main material gas and the subsidiary material gas introduced to the first gas introduction unit 60 and the second gas introduction unit 70, thereby obtaining the interlayer insulating layers 94a through 94c having desired dielectric constants and heat resistance.

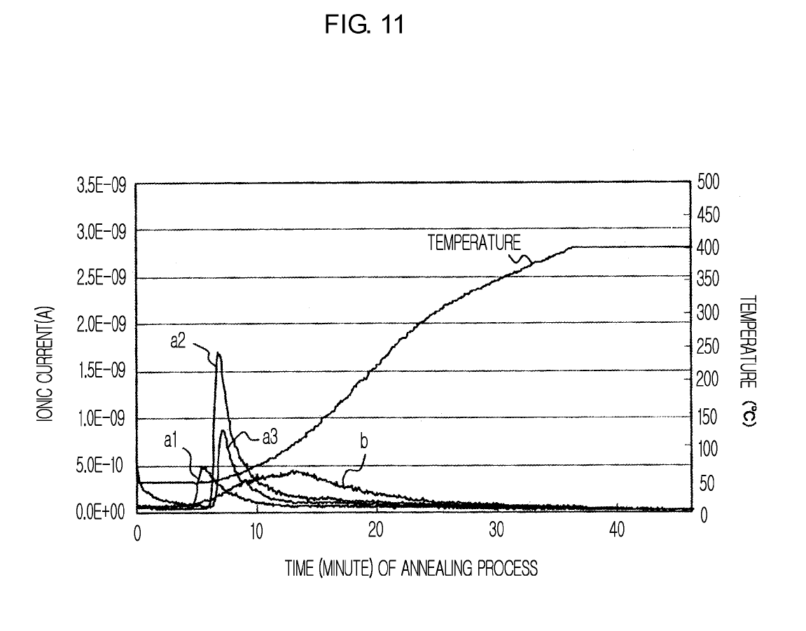

FIG. 11 is a graph showing a moisture amount separated during an annealing process of the interlayer insulating layers 94a through 94c according to time. A horizontal axis denotes a time of an annealing process, a left vertical axis denotes an ionic current, and a right vertical axis denotes temperature. The ionic current corresponds to the moisture amount separated from the interlayer insulating layers 94a through 94c. In FIG. 11, plots a1, a2, a3, and b show moisture separation tendencies of the interlayer insulating layers 94a through 94c formed under different process conditions. Film-forming temperatures of plots a1, a2, and a3 are all 350° C. and a film-forming temperature of plot b is 170° C. Also, a plasma generating gas used during film-formation is argon in plot a1, is nitrogen in plot a2, and is argon and hydrogen in plot 3. Also, a plasma generating gas used during film-formation is argon in plot ID.

As shown in FIG. 11, the interlayer insulating layers 94a through 94c formed at 350° C. have large moisture amounts separated regardless of types of the used plasma generating gas, and moisture separation is completed until an annealing process temperature reaches about 80° C. Accordingly, it is assumed that moisture included in the interlayer insulating layers 94a through 94c formed at 350° C. is not moisture included in films, but is moisture adhered mainly on a film surface.

In the interlayer insulating layer 94a through 94c formed at 170° C., a peak of a separated moisture amount is low but moisture is continuously separated until an annealing process temperature reaches 300° C. Accordingly, it is assumed that the interlayer insulating layers 94a through 94c formed at 170° C. contain moisture in films.

Generally, as the moisture amount included in films of the interlayer insulating layers 94a through 94c is low, the interlayer insulating layer is a dense film with low dielectric constants and high mechanical strength. Accordingly, the interlayer insulating layers 94a through 94c formed at 350° C. may be excellent films since they have low dielectric constants and high mechanical strength, compared to the interlayer insulating layers 94a through 94c formed at 170° C.

In the present embodiment, since the hydrocarbon group 941 and the alkyl amino group 942 are mixed in a dense amorphous structure, a space in a molecule level is formed in the interlayer insulating layers 94a through 94c. The interlayer insulating layers 94a through 94c having the space therein have low dielectric constants, compared to an interlayer insulating layer without a space. Also, since the space formed in the interlayer insulating layers 94a through 94c is a space in a molecule level different from a general porous structure, a wire delay of the semiconductor device 9 may be reduced without deteriorating the mechanical strength and anti-moisture absorption of the interlayer insulating layers 94a through 94c. Also, since the interlayer insulating layers 94a through 94c do not have a general porous structure, the problems of various impurities, such as a chemical liquid, being diffused from the vacancy or a poor barrier metal coverage caused as a vacancy is exposed to a surface of a contact hole formed in the interlayer insulating layers 94a through 94c, may be prevented.

As described above, according to the interlayer insulating layer forming method of the present embodiment, the interlayer insulating layers 94a through 94c with low in dielectric constants and excellent mechanical strength and anti-moisture absorption, compared to an interlayer insulating layer according to a conventional technology, may be formed.

Also, in the semiconductor device 9 according to the present embodiment, the wire delay may be reduced by forming the interlayer insulating layers 94a through 94c with low dielectric constants and excellent mechanical strength and anti-moisture absorption, compared to an interlayer insulating layer according to a conventional technology.

Also, by controlling target place to be supplied and supply amounts of the main material gas and the subsidiary material gas by using the process controller 80, structures of the interlayer insulating layers 94a through 94c may be easily controlled. For example, the amounts of a hydrocarbon group and an alkyl amino group mixed in an amorphous structure including hexagonal boron nitride and cubic boron nitride which are included in the interlayer insulating layers 94a through 94c may be controlled, and thus characteristics, such as a dielectric constant, a leak current, moisture absorption, an elastic modulus, and hardness, may be controlled.

Also, according to the present embodiment, properties of the interlayer insulating layers 94a through 94c are changed according to the distribution of the raw material gas supplied to the first space 1a and the second space 1b. Accordingly, properties of an interlayer insulating layer may be controlled, and thus it is possible to prepare the interlayer insulating layers 94a through 94c having desired properties, for example, desired dielectric constants, strength, and heat resistance.

In addition, since a radial line slot antenna type microwave plasma CVD apparatus can generate plasma having high electron density equal to or higher than 1×10¹¹ cm⁻³ and a low electron temperature lower than or equal to 1 to 2 eV, a semiconductor device may not be damaged and the interlayer insulating layers 94a through 94c may be formed at a high rate.

In addition, in the radial line slot antenna type microwave plasma CVD apparatus, since surface wave plasma is generated immediately below the dielectric window 50, various characteristics according to the interlayer insulating layers 94a through 94c may be easily controlled by suitably controlling the supply of gases to the first space 1a that is the plasma generating region and the second space 1b that is the diffused plasma region where the electron temperature is decreased by plasma diffusion.

Also, in the embodiments, an interlayer insulating layer is formed by using the radial line slot antenna type microwave plasma CVD apparatus, but an interlayer insulating layer may be formed by using a plasma CVD apparatus that radiates microwaves through another slot as long as it can locally generate plasma in a region spaced apart from a substrate.

Also aside from the plasma CVD apparatus that radiates microwaves through a slot, a plasma CVD apparatus using flat panel plasma, inductively coupled plasma (ICP), electron cyclotron resonance (ECR) plasma, or the like may be used. However, in this case, a semiconductor device may be damaged due to a high electron temperature or a magnetic field.

### Modified Example 1

Since an interlayer insulating layer forming apparatus according to Modified Example 1 is different only in target place to which a raw material gas and a subsidiary material gas are supplied, only the differences will now be mainly described. Table 2 below shows an example of types of gases that are supplied to the processing chamber 1 and target place of supply gases.

TABLE 2

| | | Target Place of |
|---|---|---|
| Type of Supply Gas | | Supply Gas |
| Main Material Gas | Alkyl Boron | First Space |
| | Alkyl Amino Boron | First Space |
| Subsidiary Material Gas | Ammonia | Second Space |
| | Hydrocarbon | Second Space |
| Plasma Generating Gas | Argon, Helium, Xenon, | First Space |
| | Krypton | |

As shown in Table 2 above, in Modified Example 1, alkyl boron and alkyl amino boron that are main material gases are supplied to the first space 1a, and ammonia and hydrocarbon that are subsidiary material gases are supplied to the second space 1b.

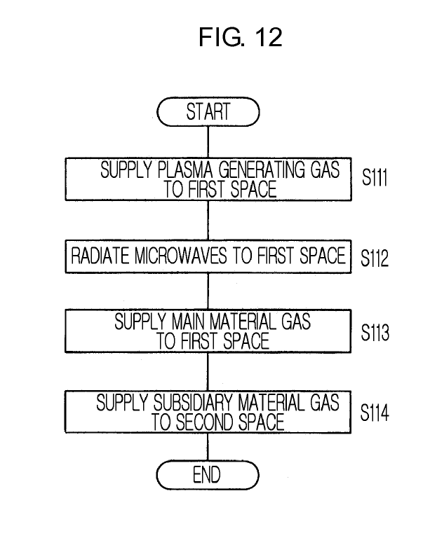

FIG. 12 is a flowchart showing a process order according to the interlayer insulating layer forming method according to Modified Example 1. The process controller 80 opens the opeing/closing valve 63c of the plasma generating gas supply source 62c to supply the plasma generating gas to the first space 1a in operation S111. Then, the process controller 80 drives the microwave generating apparatus 57 to radiate microwaves to the first space 1a in operation 5112.

Next, the process controller 80 opens the opening/closing valve 63a of the main material gas supply source 62a with respect to the first gas supply system 6 to supply the main material gas of the interlayer insulating layer to the first space 1a in operation S113. Then, the process controller 80 opens the opening/closing valve 73b of the subsidiary material gas supply source 72b with respect to the second gas supply system 7 to supply the subsidiary material gas of the interlayer insulating layer to the second space 1b in operation S114.

The same effects as the embodiments are shown in Modified Example 1. However, since an internal structure of the interlayer insulating layer is different, characteristics, such as a dielectric constant, mechanical strength, and anti-moisture permeability, are different. In detail, a ratio of the alkyl amino group mixed in the amorphous structure including the hexagonal boron nitride and the cubic boron nitride may be lower than that of the hydrocarbon group.

### Modified Example 2

Since an interlayer insulating layer forming method according to Modified Example 2 is only different in target place to which a main material gas and a subsidiary material gas are supplied, only the differences will now be mainly described. Table 3 below shows an example of types of gases that are supplied to the processing chamber 1 and target place of supply gases.

TABLE 3

| | | Target Place of |
|---|---|---|
| Type of Supply Gas | | Supply Gas |
| Main Material Gas | Alkyl Boron | First and Second |
| | | Spaces |
| | Alkyl Amino Boron | First and Second |
| | | Spaces |
| Subsidiary Material Gas | Nitrogen | First Space |
| | Ammonia | First and Second |
| | | Spaces |
| | Hydrocarbon | First and Second |
| | | Spaces |
| Plasma Generating Gas | Argon, Helium, Xenon, | First Space |
| | Krypton | |

As shown in Table 3 above, in Modified Example 2, alkyl boron and alkyl amino boron that are the main material gases are supplied to both of the first and second spaces 1a and 1b, and ammonia and hydrocarbon that are subsidiary material gases are also supplied to both of the first and second spaces 1a and 1b. Also, nitrogen that is the subsidiary material gas is supplied to the first space 1a. It is better to supply a nitrogen gas to the first space 1a instead of the second space 1b since the nitrogen gas is not dissociated and cannot be deposited on the wafer W if not supplied to the first space 1a that is the plasma generating region. Alternatively, the nitrogen gas may also be supplied to the second space 1b. Some of the nitrogen gases may be dissociated by radicals moved to the lower portion from the first space 1a.

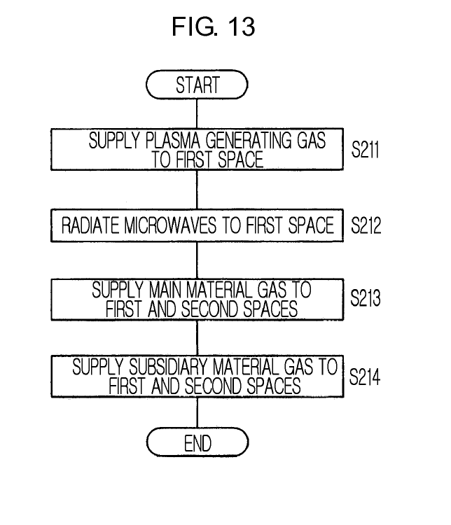

FIG. 13 is a flowchart showing a process order of the process controller 80 according to the interlayer insulating layer forming method according to Modified Example 2. The process controller 80 opens the opening/closing valve 63c of the plasma generating gas supply source 62c to supply the plasma generating gas to the first space 1a in operation 5211. Then, the process controller 80 drives the microwave generating apparatus 57 to radiate microwaves to the first space 1a in operation S212.

Next, the process controller 80 opens the opening/closing valves 63a and 73a of the main material gas supply sources 62a and 72a with respect to the first and second gas supply systems 6 and 7 to supply the main material gases of the interlayer insulating layer to the first and second spaces 1a and 1b in operation 5213. Then, the process controller 80 opens the opening/closing valves 63b and 73b of the subsidiary material gas supply sources 62b and 72b with respect to the first and second gas supply systems 6 and 7 to supply the subsidiary material gases of the interlayer insulating layer to the first and second spaces 1a and 1b in operation 5214.

The same effects as the embodiments are shown in Modified Example 2. However, since an internal structure of the interlayer insulating layer is different, characteristics, such as a dielectric constant, mechanical strength, and anti-moisture absorption, are different. In detail, a ratio of the alkyl amino group mixed in the amorphous structure including the hexagonal boron nitride and the cubic boron nitride may be lower than that in the embodiment and higher than that in Modified Example 1.

While this invention has been particularly shown and described with reference to exemplary embodiments thereof, it will be understood by those skilled in the art that various changes in form and details may be made therein without departing from the spirit and scope of the invention as defined by the appended claims.

### LIST OF REFERENCE NUMERALS

1: Processing Chamber
1a: First Space
1b: Second Space
6: First Gas Supply System
7: Second Gas Supply System
9: Semiconductor Device
60: First Gas Introduction Unit
70: Second Gas Introduction Unit
62a, 72a: Main Material Gas Supply Source
62b, 72b: Subsidiary Material Gas Supply Source
62c: Plasma Generating Gas Supply Source
80: Process Controller
81: User Interface
82: Storage Unit
91: Wafer Substrate
92: MOSFET
93: Oxide Film
94a to 94c: Interlayer insulating Layer
941: Hydrocarbon Group
942: Alkyl Amino Group
W: Wafer

1. An interlayer insulating layer forming method for forming an interlayer insulating layer of a semiconductor device via a plasma CVD method, the interlayer insulating layer comprising:
carrying a substrate into a depressurized processing container;
supplying a plasma generating gas to a first space spaced apart from the substrate;
exciting the plasma generating gas in the first space; and
supplying a raw material gas comprising a boron compound that comprises at least a hydrogen group or hydrocarbon group, to a second space between the first space and the substrate.

2. The interlayer insulating layer forming method of claim 1, wherein the exciting of the plasma generating gas comprises using microwaves radiated into the processing container through a slot.

3. The interlayer insulating layer forming method of claim 1, wherein the raw material gas comprises boron, carbon, and nitrogen.

4. The interlayer insulating layer forming method of claim 1, wherein the raw material gas comprises alkyl boron or alkyl amino boron.

5. The interlayer insulating layer forming method of claim 1, wherein ammonia or a hydrocarbon gas is supplied to at least any one of the first space and the second space.

6. The interlayer insulating layer forming method of claim 1, wherein a nitrogen gas is supplied to the first space.

7. (canceled)

8. (canceled)
